(19) United States
(12) Patent Application Publication
(10) Pub. No.: US 2025/0102597 A1
(43) Pub. Date: Mar. 27, 2025

(54) REMOTELY MONITORED LEAKAGE CURRENT METER

(71) Applicant: Hubbell Incorporated, Shelton, CT (US)

(72) Inventors: Michael David Carson, Somers, NY (US); Matthew E. Weintraub, Danbury, CT (US); Richard William Osmers, Danbury, CT (US); Lawrence Clifford Studwell, South Plainfield, NJ (US)

(73) Assignee: Hubbell Incorporated, (US)

(21) Appl. No.: 18/890,101

(22) Filed: Sep. 19, 2024

Related U.S. Application Data
(60) Provisional application No. 63/584,655, filed on Sep. 22, 2023.

(51) Int. Cl. G01R 31/52; B66F 17/00

(52) U.S. Cl. CPC G01R 31/52; B66F 17/006

(57) ABSTRACT

A leakage current meter can be mounted on a power company bucket-truck with the capability to detect an excessive amount of leakage current and send an alarm signal through harsh or extreme levels of EMI to a remote unit up in the bucket, causing an audible alarm in the bucket.

### RELATED APPLICATION(S)

This application claim priority to U.S. Provisional Application No. 63/584,655, filed Sep. 22, 2023, the disclosure of which is hereby incorporated by reference in its entirety.

### TECHNICAL FIELD

Various embodiments of the present invention relate to measurement devices and methods of using the same, and in particular, to leakage current meters and methods of using the meters to sense leakage current from a high-power line to a utility bucket-truck.

### BACKGROUND

Utility companies and construction crews often use a bucket-truck when work needs to be done high off the ground. The bucket-truck has a “bucket” in the form of a platform with rails suitable for the utility lineman to stand in. The bucket is affixed to a multi-section boom arm that can be extended and moved around to position it near an object to be worked on or inspected. A bucket-truck is often used to lift a utility lineman or other worker up near a high voltage line to perform repairs or inspection.

It would be extremely dangerous to use a non-insulated bucket-truck near high voltage lines. Therefore, utility companies and contractors doing such work provide insulated bucket-trucks for work or inspection near high voltage lines. At least one—or often two of the boom arm components—of these insulated bucket-trucks are constructed of fiberglass or other non-conducting material to prevent conduction of electricity between the high voltage line and the ground. In this way the bucket can be at the same potential as the high voltage line while the truck itself remains grounded without danger to the utility lineman in the bucket. To ensure proper insulation between the bucket and the truck a leakage current meter is kept on the truck. The leakage current meter detects current passing through the boom to ground. The Von™ model BCM-44 is a widely used leakage current meter in usage today. The model BCM-44 leakage current meter may be used by utility lineman on the ground to monitor for potentially dangerous leakage current conditions. The model BCM-44 leakage current meter has an audible alarm intended to indicate a dangerous leakage condition to the utility lineman up in the bucket.

### SUMMARY

The present inventors recognized a need for additional capabilities in measuring leakage current as well as a number of drawbacks in conventional leakage current meters. For example, a conventional leakage current meter located on the bed of a bucket-truck uses a buzzer or other type of audible alarm to communicate a potentially dangerous leakage current condition up to the utility worker in the bucket. Depending on the background noises that is present, the audible alarm sometimes cannot be heard by the person in the bucket—e.g., noise from the idling bucket-truck's engine, traffic noise or noise from nearby construction equipment.

In addition to this, the audible buzzer only provides an indication of two states: safe or unsafe. A person on the ground looking at the screen of the conventional leakage current meter can see the readings, but the utility worker up on the bucket has no way knowing what the meter reading is indicating. The various embodiments disclosed herein overcome these and other disadvantages, and provide benefits and capabilities not available in the prior art meters, as discussed in the paragraphs below and illustrated in the drawings.

### BRIEF DESCRIPTION OF THE DRAWINGS

The accompanying drawings, which are incorporated in and constitute part of the specification, illustrate various embodiments of the invention. Together with the general description, the drawings serve to explain the principles of the invention. In the drawings:

FIG. 1 is an oblique view of a bucket-truck equipped with a leakage current meter according to various embodiments disclosed herein.

FIG. 2 depicts various communication links and pathways for a leakage current meter mounted on a bucket-truck according to various embodiments disclosed herein.

FIGS. 3A-B depict block diagrams of leakage current meters according to various embodiments disclosed herein.

### DETAILED DESCRIPTION OF EXEMPLARY CONFIGURATIONS

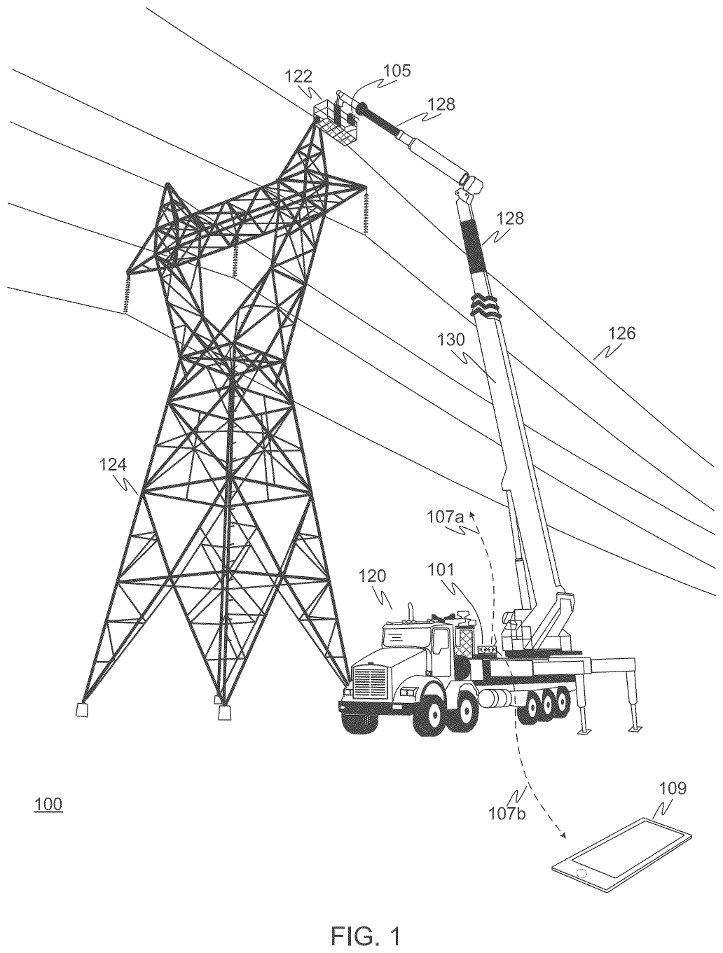

FIG. 1 is an oblique view 100 of a bucket-truck 120 equipped with a leakage current meter 101 according to various embodiments disclosed herein. Utility companies often need to perform repairs or inspections on high-power lines 126 and transmission towers 124. This is typically done using a bucket-truck 120 to lift a utility lineman or other worker up near the transmission tower 124 or high-power lines 126. The truck body of the bucket-truck 120 sits on the ground and is typically grounded in an electrical sense. The bucket 122 is held up and moved by a boom arm 130. If a bucket-truck 120 is going to be used near high-power lines 126, the boom arm 130 typically includes one or more non-conducting segments 128 as a safety measure. The non-conducting segments 128 electrically insulate the bucket 122 from the truck body which is at ground potential. The non-conducting segments 128 may be made from fiberglass or other insulator material of sufficient strength. This prevents current from arcing from the high-power line 126 to the bucket 122 and down through the boom arm 130 to ground.

Leakage current passing through the bucket-truck arm 130 to ground poses a danger to the utility lineman up in the bucket 122 and workers on the ground near the bucket-truck 120. To avoid unsafe conditions a leakage current meter 101 mounted on bucket-truck 120 is used to detect current passing through the bucket-truck arm 130 to ground. The leakage current meter 101 is typically mounted on the bucket-truck 120 using bolts or screws, but may be mounted using adhesives or other ways of affixing two devices together as are known to those of ordinary skill in the art. In some implementations, a bracket is mounted on the bucket-truck 120 and the current meter 101 is affixed to the bracket—e.g., slid into or snapped onto the bracket or bolted/screwed to the bracket. In such implementations the bracket is considered to be part of the current meter 101.

Conventional current meters have an audible alarm intended to indicate a potentially dangerous leakage condition to the utility lineman up in the bucket 122. However, the present inventors recognized that it is often difficult, and sometimes impossible, for the utility lineman up in the bucket 122 to hear the conventional audible alarm which, for conventional current meters, is down at the bucket-truck 120.

Various embodiments of the leakage current meter 101 disclosed herein provide a leakage current meter 101 mounted on the bucket-truck 120 and an audible alarm up in the bucket 122 to ensure that the utility lineman in the bucket 122 can hear it. The leakage current meter 101 mounted on the bucket-truck 120 may also have a speaker 101-1 that sounds an audible alarm as well as a display 101-2 (e.g., a digital display) that communicates the value of the leakage current being detected and other information for setting up and operating the leakage current meter 101. For example, a digital display (e.g., an LED screen, an LCD screen, etc.) may display human-readable text. In other examples, the digital display may display symbols or patterns (e.g., a sequence of lights) that may equate to the value of the leakage current. The leakage current meter 101 has various controls 101-3 to set up and operate the meter, including for example: an ON/OFF switch, a control to adjust the predefined leakage current threshold for the alarm, a control to adjust the audible alarm volume, and the like.

In various embodiments the utility lineman up in bucket 122 may have a remote indicator unit 105. The remote indicator unit 105 has a speaker configured to provide an audible warning alarm up in the bucket 122 in the event leakage current above a predefined leakage current threshold is detected at the bucket-truck 120 by the current meter 101. The current meter 101 mounted at the bucket-truck 120 transmits signals—including an alarm indication signal—to the remote indicator unit 105 up in the bucket 122 via a truck-to-bucket communication link 107a. The current meter 101 may also transmit signals to a communication device 109 via a data communication link 107b. The communication device 109 is typically in the possession of a supervisor or other utility worker on the ground or in the bucket-truck 120. The communication device 109 may be implemented as a smart phone with an app on it to receive, display and store data from the current meter 101. The communication device 109 may also be implemented as a laptop or notebook computer or other computing device with a microprocessor, storage capabilities and the ability to send and receive signals.

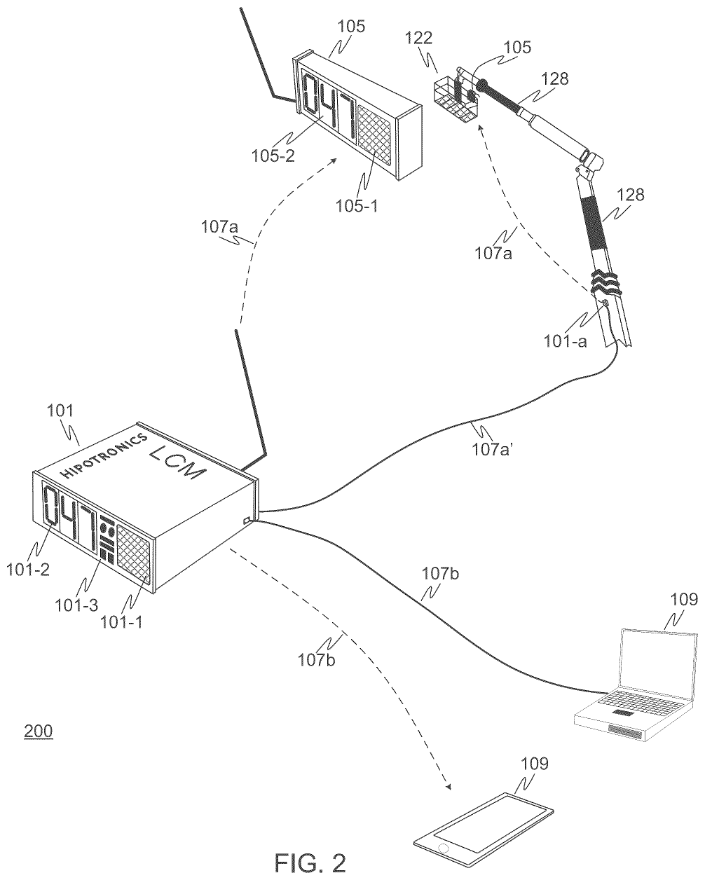

FIG. 2 is a depiction 200 of various communication links and pathways for the truck-mounted leakage current meter 101 according to various embodiments disclosed herein. Some of the various embodiments may be implemented by sending signals from the truck-mounted leakage current meter 101 via cellular telephone signals to a smart phone of the utility lineman in bucket 122. However, the use of cell phone signals tends to be susceptible to communication interruptions due to the large electro-magnetic interference (EMI) near the high-power lines 126. So the utility lineman up in bucket 122 generally experiences poorer cell phone reception as the bucket 122 gets closer to high-power lines 126.

EMI is caused by high levels of EMF (electromotive force) near the high-power lines 126. EMF is commonly measured in units of milligauss (mG). Levels of EMF throughout a typical home often vary from 0.5 to 5 mG with the highest EMF level generally occurring near the house's junction box where electricity enters the home and is distributed throughout. High voltage high-power lines (e.g., high-power line 126 of FIG. 1) cause much higher levels of EMF. The amount of EMF directly under a high-power line 126 may range from 30 to 90 mG. This high EMF environment can be enough to cause interference with cellular telephone signals, in some instances, depending on the strength of the cell phone signal in relation to the amount of EMF. But the levels of EMF increase considerably up at the bucket 122 which is sometimes positioned within a couple feet from high-power lines 126. With the bucket up near the high-power lines 126, the utility lineman will sometimes be in an extreme EMF environment where levels of EMF may be greater than 200 mG.

To overcome the extreme EMI environment that the utility lineman in the bucket 122 often experiences, various embodiments disclosed herein are implemented using EMI resistant communication protocols. One such EMI resistant communication protocol is CAN (controller area network). CAN is a robust EMI resistant communication protocol suitable for use over the truck-to-bucket communication link 107a. The CAN protocol may be implemented wirelessly or used on a hardwired data line. CAN is capable of being transmitted wirelessly up to 500 meters, has built in error detection, and a data rate of up to 1 Mbps. While the CAN data rate is considerably less than other well-known communication protocols (e.g., Ethernet with data rates in the Gbps range), the CAN data rate of up to 1 Mbps is certainly adequate to transmit the leakage current data and warning signals from the current meter 101 to a receiver in the bucket 122. Alternatively, in lieu of the CAN communication protocol, the various embodiments may be implemented with any EMI-resistant communication protocol known to those of ordinary skill in the art.

In some embodiments, a remote wireless transmitter 111 may be positioned up on the boom arm 130 (e.g., just under the lowest non-conducting segment 128). The remote wireless transmitter 111 may be hardwired via data line 107a′ to the leakage current meter 101. Placing the remote wireless transmitter 111 up on the boom arm 130 reduces the wireless distance of communication link 107a to the remote indicator unit 105 through a harsh or extreme EMI environment. In other embodiments a hardwired data line may be used for the entirety of communication link 107a from the current meter 101 up to the remote indicator unit 105 in the bucket 122. In such implementations it is preferable to use a non-conductive data line such as a fiber optic cable to avoid the possibility of accidentally shorting the bucket 122 to ground. Another alternative is to use a regular conductive hardwired data line for the communication link 107a (e.g., twisted pair or a copper line), but with an in-line fuse or fusible link that would blow (open circuit) upon the application of an appreciable current, e.g., 0.2 amp. The hard-wired lines used as communication link 107a experience the disadvantage of catching on the boom arm 128, or twisting and possibly breaking as the boom arm 128 is moved around and raised from the ground. Use of a wireless communication link 107a avoids these disadvantages.

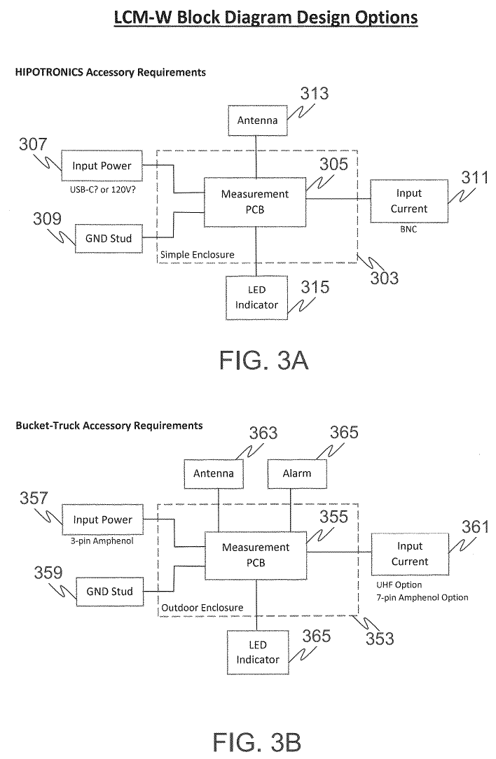

In the various embodiments the remote indicator unit 105 has a speaker 105-1 to sound a warning alarm in response to leakage current in excess of a predetermined threshold being detected down at the leakage current meter 101 mounted on the bucket-truck 120. The leakage current threshold at which the alarm sounds may be adjusted at the leakage current meter 101. A typical setting for the leakage current threshold is somewhere in the range of 0.2 uA/1 kV to 5 uA/1 kV—e.g., 1 uA/1 kV. In various embodiments the meter may be adjusted to thresholds as low as 0.1 uA/1 kV (i.e., a tenth of a microamp) to as high as 10 mA/1 kV (10 milliamps). Depending on the requirements of the implementation, circuitry of the leakage current meter can be provided to have a higher or lower threshold than this (e.g., printed circuit board 305 of FIG. 3A). The remote indicator unit 105 may also have a display 105-2 (e.g., a digital display) to display the level of leakage current being detected, or other information of the leakage current meter 101 such as the settings—e.g., the alarm volume level, ON/OFF state, wireless connection to the remote indicator unit 105 in bucket 122, etc.

FIGS. 3A-B depict functional block diagrams of leakage current meters 301 and 351 according to various embodiments disclosed herein. FIG. 3A is a standard leakage current meter 301 suitable for use in a lab or factory setting. FIG. 3B is a functional block diagram of a bucket-truck leakage current meter 351 suitable for use on a bucket-truck 120 or other outdoor setting where there is a possibility of dangerous leakage current conditions.

FIG. 3A depicts a leakage current meter 301 with a current measurement printed circuit board (PCB) 305 mounted in an enclosure 303. The printed circuit board 305 has circuitry for making current measurements and controlling the outputs (e.g., LEDs or audible alarm). The enclosure 303 is designed to keep people and items from touching the printed circuit board 305 and damaging it or injuring themselves. It should be noted that the standard enclosure 303 is meant to be used indoors or in dry conditions and is not necessarily waterproof. A power connector 307 is mounted on the enclosure 303, connecting a source of power to the printed circuit board 305. Depending upon the implementation, the power connector 307 may receive power from a 120 VAC standard electrical outlet, or may be a USB female connector and receive power via a USB pin (e.g., USB-C, USB-A, etc.). The enclosure 303 also has a ground stud 309 to tie the enclosure to electrical ground.

A current input port 311 is configured to accept an input current for measurement. The current input port 311 may be a BNC connector, an SMA connector, or other standard connector type known to those of ordinary skill in the art. An antenna 313 passes received/transmitted signals through the enclosure 303 to a receiver/transmitter. The receiver/transmitter may be part of the printed circuit board 305, or may be configured as a separate unit that cooperates with the printed circuit board 305. The standard leakage current meter 301 has an LED indicator 315 mounted on enclosure 303. Depending upon the implementation, the LED indicators 315 may include one or more of: a single LED light indicating leakage current exceeding a predefined threshold, an LED power light indicating the ON/OFF state of the standard leakage current meter 301, and multiple BCD digit LEDs to indicate the numerical value and bias of a detected leakage current. The standard leakage current meter 301 may, in some implementations, have an audible alarm (not shown) to indicate the leakage current exceeding a predefined threshold. The standard leakage current meter 301 also has controls for setting the leakage current threshold and other parameters and settings of the device.

FIG. 3B depicts a bucket-truck leakage current meter 351 and its component parts. The bucket-truck leakage current meter 351 may be used in the manner described above for bucket-truck leakage current meter 101. Many of the component parts are similar to those of the standard leakage current meter 301 depicted in FIG. 3A. One difference is that the bucket-truck leakage current meter 351 is designed to be used outdoors, and as such, is designed to withstand weather conditions. For example, the outdoor enclosure 353 is designed to be waterproof (or at least or water resistant), and the various ports, inputs and outputs are designed to either be waterproof or water resistant.

The bucket-truck leakage current meter 351 has a current measurement printed circuit board 355, a power connector 357, and a current input port 361. The current input port 361 may be a BNC connector, an SMA connector, a 7-pin Amphenol™ connector, or other standard connector type known to those of ordinary skill in the art. The bucket-truck leakage current meter 351 has an antenna 363, an audible alarm 367, and LED indicators 365 mounted on enclosure 353. The operation of the various components of the bucket-truck leakage current meter 351 is similar to that described for the standard leakage current meter 301, except in a ruggedized, weatherproof case.

The standard leakage current meter 301 and bucket-truck leakage current meter 351 may each have memories or other data storage devices and one or more transmitter/receivers to send and receive data. The memories or other data storage devices may be incorporated on the printed circuit board 305/355, or may be implemented as separate units that interface and connect with the printed circuit board 305/355. The memory (or other storage device) stores detected leakage current readings, and may be used to store programs, routines or logic to operate the leakage current meters 301/351. The transmitter/receivers may be configured to send and receive leakage current readings, warning indications, and controls for operating the system. Each of the leakage current meters 301/351 may have multiple transmitter/receivers, for example, one transmitter/receiver to communicate via truck-to-bucket communication link 107a with the 105 remote indicator unit 105 up in bucket 122 of FIGS. 1-2, and another transmitter/receiver to communicate via data communication link 107b with a communication device 109 as shown in FIGS. 1-2.

The system may be programmed to collect, store and analyze various types and amounts of data. For example, leakage data of leakage current readings taken over time for a given bucket-truck may be stored and analyzed to determine insulation degradation trends and possibly predict failures in the insulative bucket arm segment—e.g., non-conducting segments 128 of FIG. 1.

Various embodiments are discussed for use with or being mounted on a bucket-truck with a movable bucket suitable for lifting a utility lineman. A bucket-truck is a truck with a movable arm (e.g., moved by operator controlled hydraulic cylinders) capable of lifting a bucket or platform large enough for a 5′ 9″ person to ride in or on. A Versalift™ SST-36-NE mounted on a 2022 Dodge Ram truck is an example of a bucket truck.

Various embodiments are discussed in terms of operating in high EMF levels, in harsh EMF levels, and sometimes in extreme” EMF levels. For the purposes of this disclosure, a “high EMF level” (sometimes called a “high EMF environment”) is defined as being greater than 30 mG (milligauss) but less than 100 mG. A “harsh EMF level” (sometimes called a “harsh EMF environment”) is defined as being 100 mG or greater but less than 200 mG. An “extreme EMF level” (sometimes called an “extreme EMF environment”) is defined as being equal to or greater than 200 mG. The various embodiments are disclosed to be implemented using an EMI-resistant communication protocol such as CAN which is suitable for use in an extreme EMF environment. In this context, a communication protocol is defined to be “EMI-resistant” if it can reliably transmit data in the presence of extreme EMF levels (e.g., 201 mG). A device or protocol can “reliably transmit” data if there is a 90% or great chance of communicating 10 kbytes of data within 10 seconds of the end of the 10 kbyte data transmission.

For the purposes of this disclosure the remote indicator unit 105 may be considered part of the leakage current meter 101 since it is communicatively coupled to the leakage current meter 101 to receive alarm signals from it. By “communicatively coupled” it is meant that the remote indicator unit at least receives signals from the leakage current meter (e.g., the alarm signal) and may in some embodiments also be configured to transmit signals to the leakage current meter.

The disclosure of the various embodiments refers to the enclosure as being weatherproof. The International Electrotechnical Commission (IEC) uses an Ingress Protection (IP) rating consisting of two numerals to rate the degree of protection afforded by an enclosure. The IEC's IP rating system is described and explained in a document identified as International Standard IEC 60529 with amendments incorporated through January 2019. IP ratings are written in the format: IP35. The first digit of the IP rating has a value of from 0 to 6 and specifies protection from solids, e.g., dust and other particles. The second digit of the IP rating has a value of from 0 to 9 and specifies protection from liquids, e.g., water, jets of water, etc. The highest IP rating possible is IP69. An X in either digit of an IP rating means that the X digit is not rated. For the purposes of this disclosure, an enclosure or other container with an IP rating of IPX3 or greater is considered “weatherproof.”

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes,” and/or “including” used in this specification specify the presence of stated features, integers, steps, operations, elements, and/or components, but do not preclude the presence or addition of one or more other features, integers, steps, operations, elements, components, and/or groups thereof. The term “plurality”, as used herein and in the claims, means two or more of a named element. It should not, however, be interpreted to necessarily refer to every instance of the named element in the entire device. Particularly, if there is a reference to “each” element of a “plurality” of elements. There may be additional elements in the entire device that are not be included in the “plurality” and are not, therefore, referred to by “each.”

The description of the various embodiments provided above is illustrative in nature inasmuch as it is not intended to limit the invention, its application, or uses. Thus, variations that do not depart from the intents or purposes of the invention are intended to be encompassed by the various embodiments of the present invention. Such variations are not to be regarded as a departure from the intended scope of the present invention.

What is claimed is:

1. A leakage current meter for a bucket-truck with a movable bucket suitable for lifting a utility worker, the leakage current meter comprising:
an enclosure with a front face;
leakage current measurement circuitry mounted within the enclosure;
a first transmitter configured to reliably transmit first wireless signals to the movable bucket in a harsh EMF environment;
a speaker mounted within the enclosure and configured to signal an audible warning alarm;
wherein the first transmitter transmits first wireless signals in response to the leakage current measurement circuitry detecting leakage current exceeding a predetermined leakage current threshold.

2. The leakage current meter of claim 1, wherein the speaker signals an audible alarm in response to the leakage current measurement circuitry detecting the leakage current to exceed the predetermined leakage current threshold.

3. The leakage current meter of claim 2, wherein the enclosure is weatherproof, the leakage current meter further comprising:
a second transmitter configured transmit second wireless signals to a communication device.

4. The leakage current meter of claim 3, wherein the speaker is a first speaker and the audible warning alarm is a first audible warning alarm, the leakage current meter further comprising:
a remote indicator unit positioned on the movable bucket.

5. The leakage current meter of claim 4, further comprising:
a second speaker configured as part of the remote indicator unit;
wherein the second speaker sounds a second audible warning alarm in response to the remote indicator unit receiving first wireless signals from the first transmitter.

6. The leakage current meter of claim 5, wherein the predetermined leakage current threshold is a value within 0.2 uA/1 kV to 5 uA/1 kV.

7. The leakage current meter of claim 1, further comprising:
a display on the front face;
wherein the display is configured to communicate a value of the leakage current being measured by the leakage current measurement circuitry.

8. The leakage current meter of claim 7, wherein the first transmitter is configured to transmit first wireless signals using an EMI-resistant protocol.

9. The leakage current meter of claim 8, wherein the EMI-resistant protocol is CAN (controller area network).

10. The leakage current meter of claim 9, wherein the utility worker is a human at least 5′ 9″ tall and weighing at least 170 lbs.; and
wherein the leakage current meter is mounted on the bucket-truck.

11. The leakage current meter of claim 10, wherein the second wireless signals are transmitted using wi-fi to the communication device.

12. A leakage current detection system for a bucket-truck with a movable bucket suitable for lifting a utility worker, the leakage current detection system comprising:
a current meter including:
an enclosure with a front face,
leakage current measurement circuitry mounted within the enclosure, and
a first transmitter configured to transmit first wireless signals to the movable bucket in a harsh EMF environment; and
an indicator unit located remote from the current meter and configured to be mounted within the enclosure, the indicator unit including:
a receiver configured to receive the first wireless signals, and
an output device configured to communicate information to a utility worker;
wherein the first transmitter transmits first wireless signals in response to the leakage current measurement circuitry detecting leakage current exceeding a predetermined leakage current threshold.

13. The leakage current detection system of claim 12, wherein the output device includes a speaker configured to output an audible alarm, the speaker signals an audible alarm in response to the leakage current measurement circuitry detecting the leakage current to exceed the predetermined leakage current threshold.

14. The leakage current detection system of claim 12, wherein the output device includes a display configured to output a visual indication that communicates a value of the leakage current being measured by the leakage current measurement circuitry.

15. The leakage current detection system of claim 12, wherein the first transmitter is configured to transmit first wireless signals using an EMI-resistant protocol, and wherein the EMI-resistant protocol is CAN (controller area network).

16. The leakage current detection system of claim 12, wherein the enclosure is weatherproof, the leakage current meter further comprising: a second transmitter configured transmit second wireless signals to a communication device.

17. The leakage current detection system of claim 12, wherein the predetermined leakage current threshold is a value within 0.2 uA/1 kV to 5 uA/1 kV.

18. The leakage current detection system of claim 12, wherein:
the output device includes a speaker configured to output an audible alarm and a display configured to output a visual indication, the speaker and the display configured to each output a signal based on the first wireless signal.

19. The leakage current detection system of claim 12, further comprising a second speaker mounted within the enclosure and configured to signal an audible warning alarm.

20. The leakage current detection system of claim 12, wherein the audible warning alarm communicates the same information as the output device.
